(19) United States
(12) Patent Application Publication
(10) Pub. No.: US 2009/0065811 A1
(43) Pub. Date: Mar. 12, 2009

(54) Semiconductor Device with OHMIC Contact and Method of Making the Same

(76) Inventors: Ping-Chih Chang, Gardena, CA (US); Xiaobing Mei, Manhattan Beach, CA (US); Augusto Gutierrez-Aitken, Redondo Beach, CA (US)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 11/851,968

(22) Filed: Sep. 7, 2007

(51) Int. Cl. H01L 29/737; H01L 21/3205

(52) U.S. Cl. 257/197; 438/605; 257/E21.294; 257/E29.188

(57) ABSTRACT

A semiconductor device with ohmic contact is provided with a method of making the same. In one embodiment, a method is provided for fabricating a semiconductor device. The method comprises providing a semiconductor structure with a N-type doped semiconductor contact layer, forming a platinum contact portion over the N-type doped semiconductor contact layer, forming an adhesive contact portion over the platinum contact portion, forming a barrier contact portion over the adhesive contact portion, and forming a gold contact portion over the barrier contact portion. The method further comprises annealing the semiconductor structure to alloy the platinum contact portion with the N-type doped semiconductor contact layer to form a platinum/semiconductor alloyed diffusion contact barrier substantially disposed within the N-type doped semiconductor contact layer.

### TECHNICAL FIELD

The present invention relates generally to semiconductors, and more particularly to a semiconductor device with ohmic contact and method of making the same.

### BACKGROUND OF THE INVENTION

Heterojunction bipolar transistors (HBTs) are widely used in high speed and high frequency applications. The heterojunction bipolar transistor (HBT) offers much higher speeds of operation than the more prevalent metal-oxide-semiconductor field-effect transistors (MOSFETS) or even conventional homojunction bipolar transistors, such as npn or pnp silicon transistors. The HBT offers an alternative technology to metal semiconductor field effect transistors (MESFETs) and high electron mobility transistors (HEMTs) when a high degree of linearity is desirable. The use of different materials of differing bandgaps for the collector, base and emitter provides for additional design flexibility. The HBT is a layered structure that includes a semiconductor substrate, a subcollector, a collector, a base and an emitter stacked one on top the other in an integral assembly. Metal contacts are formed to connect power and other circuitry to the emitter, the base and the subcollector.

Emitter contact resistance is very important to HBT performance, such that the lower the emitter contact resistance the better the performance. One type of low resistance n-type emitter contact is formed from subsequent layers of titanium (Ti), platinum (Pt) and gold (Au). However, the gold will diffuse into the semiconductor through the platinum and titanium over time causing reliability issues. Another type of low resistance n-type emitter contact is formed from subsequent layers of alloyed germanium (Ge), gold (Au) and nickel (Ni). However, the germanium and gold will react over time with the semiconductor causing uncontrolled metal diffusion resulting in reliability issues.

Platinum (Pt) has been used to form a reactive layer with p-type GaAs to form p-Ohmic base contact on Gallium Arsenide (GaAs) based heterojunction bipolar transistors (HBTs), which has shown to be a stable compound that would prevent further diffusion of additional metal stacked above the platinum (Pt)/Gallium Arsenide (GaAs) alloy. However, the platinum (Pt) has a workfunction of ˜4.6 eV, which allows an energy band alignment that is suitable for low resistance p-Ohmic contact on Gallium Arsenide (GaAs), which has an electron affinity value of ˜4.1 eV. Due to the high energy workfunction of the platinum (Pt) contact, it is commonly used to form the Schottky contact on n-type Gallium Arsenide (GaAs) based devices.

### SUMMARY OF THE INVENTION

In one aspect of the invention, a method is provided for fabricating a semiconductor device. The method comprises providing a semiconductor structure with a N-type doped semiconductor contact layer, forming a platinum contact portion over the N-type doped semiconductor contact layer, forming an adhesive contact portion over the platinum contact portion, forming a barrier contact portion over the adhesive contact portion, and forming a gold contact portion over the barrier contact portion. The method further comprises annealing the semiconductor structure to alloy the platinum contact portion with the N-type doped semiconductor contact layer to form a platinum/semiconductor alloyed diffusion contact barrier substantially disposed within the N-type doped semiconductor contact layer.

In another aspect of the invention, a method is provided for fabricating an Indium Phosphide (InP) based heterojunction bipolar transistor (HBT) device. The method comprises providing a HBT device with a N-type doped emitter contact layer, forming a first platinum contact portion over the N-type doped emitter contact layer, forming a titanium contact portion over the first platinum contact portion, forming a second platinum contact portion over the titanium contact portion, and forming a gold contact portion over the barrier contact portion. The method further comprises annealing the HBT at a temperature of about 200° C. to about 300° C. for about 15 minutes to about 60 minutes to alloy the first platinum contact portion with the N-type doped emitter contact layer to form a platinum/semiconductor alloyed diffusion contact barrier substantially disposed within the emitter contact layer.

In yet another aspect of the invention, an Indium Phosphide (InP) based heterojunction bipolar transistor (HBT) device is provided. The HBT device comprises a N-type doped emitter contact layer, a platinum/semiconductor alloyed diffusion contact barrier substantially disposed within the N-type emitter contact layer, an adhesive contact portion overlying the platinum/semiconductor alloyed diffusion contact barrier, a barrier contact portion overlying the adhesive contact portion and a gold contact portion overlying the barrier contact portion.

### BRIEF DESCRIPTION OF THE DRAWINGS

FIG. 1 illustrates a schematic cross-sectional view of a HBT device structure with an ohmic contact in accordance with an aspect of the present invention.

FIG. 2 illustrates a schematic cross-sectional view of a HBT structure prior to formation of the ohmic contact in accordance with an aspect of the present invention.

FIG. 3 illustrates a schematic cross-sectional view of the HBT structure of FIG. 2 after formation of a platinum contact portion of the ohmic contact in accordance with an aspect of the present invention.

FIG. 4 illustrates a schematic cross-sectional view of the HBT structure of FIG. 3 after formation of an adhesive contact portion overlying the platinum contact portion of the ohmic contact in accordance with an aspect of the present invention.

FIG. 5 illustrates a schematic cross-sectional view of the HBT structure of FIG. 4 after formation of a barrier contact portion overlying the adhesive contact portion of the ohmic contact in accordance with an aspect of the present invention.

FIG. 6 illustrates a schematic cross-sectional view of the HBT structure of FIG. 5 after formation of a gold contact portion overlying the barrier contact portion of the ohmic contact in accordance with an aspect of the present invention.

FIG. 7 illustrates a schematic cross-sectional view of the HBT structure of FIG. 6 undergoing an annealing of the HBT structure to form the platinum/semiconductor alloyed contact barrier of FIG. 1 in accordance with an aspect of the present invention.

### DETAILED DESCRIPTION OF INVENTION

The present invention relates to an ohmic contact for an N-type doped semiconductor contact layer. The ohmic contact can be employed on a HBT device to facilitate the reduction of contact resistance and to increase reliability by mitigating diffusion of portions of the contact into the N-typed doped semiconductor. The ohmic contact employs a platinum/semiconductor alloyed diffusion contact barrier substantially disposed within the N-type doped semiconductor to mitigate diffusion of overlying contact portions of the ohmic contact into the N-type doped semiconductor. The platinum/semiconductor alloyed diffusion contact barrier can be formed by providing a platinum contact portion over the N-typed doped semiconductor and annealing the HBT device to diffuse the platinum into the N-type semiconductor to form the platinum/semiconductor alloyed diffusion contact barrier. The ohmic contact can further include an adhesive contact portion overlying the platinum/semiconductor alloyed diffusion barrier, a barrier contact portion overlying the adhesive contact portion and a gold contact portion overlying the barrier contact portion. The ohmic contact provides a very low resistance contact that is substantially unaffected by contamination and protects against contact diffusion facilitating longevity and reliability.

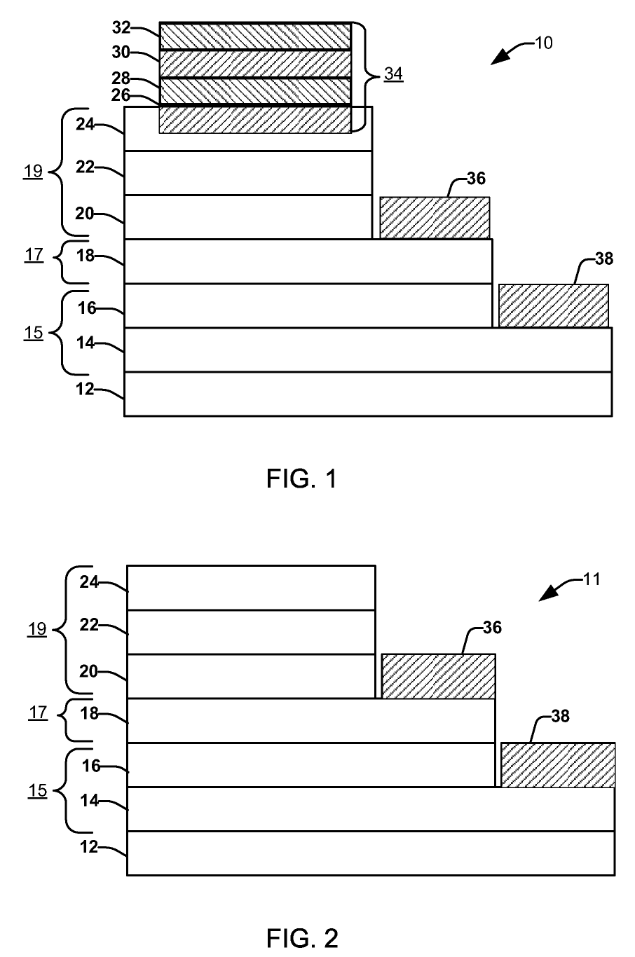

FIG. 1 illustrates a schematic cross-sectional illustration of a HBT device 10 in accordance with the present invention. The device structure 10 includes an Indium Phosphide (InP) substrate wafer 12. The InP substrate 12 provides mechanical support for the device 10, and is of a thickness suitable for providing such support. The device 10 includes a collector portion 15 disposed on the InP substrate 12, a base portion 17 disposed on the collector portion 15 and an emitter portion 19 disposed on the base portion 17. The collector portion 19 includes a subcollector layer 14 overlying the InP substrate 12 and a collector layer 16 overlying the subcollector layer 14. The subcollector layer 14 is coupled to a collector contact 38 and can be formed of heavily doped n+Indium Gallium Arsenide (InGaAs). The collector layer 16 can be formed of lightly doped n− InGaAs or InP. The base portion 17 includes a base layer 18 overlying the collector layer 16. The base layer 18 is coupled to a base contact 36 and can be heavily doped p+ InGaAs or Gallium Arsenide Antimonide (GaAsSb).

The emitter portion 19 includes a first emitter layer 20 overlying the base layer 18, a second emitter layer 22 overlying the first emitter layer 20 and an emitter contact layer 24 overlying the second emitter layer 22. The first emitter layer 20 can be formed of lightly doped n− Indium Aluminum Arsenide (InAlAs) or InP and the second emitter layer 22 can be formed of heavily doped n+ InAlAs or InP. The emitter contact layer 24 is coupled to an emitter contact 34 and can be formed of heavily doped n+ InGaAs. The emitter contact 34 includes a platinum/semiconductor alloyed diffusion contact barrier 26 that is disposed substantially within the emitter contact portion 24 and has a thickness of about 50 Å to about 200 Å. The platinum/semiconductor alloyed diffusion contact barrier 26 can be formed by providing a platinum contact portion overlying the emitter contact portion 24 and annealing the HBT device 10 to alloy the platinum with the semiconductor of the emitter contact layer 24. The HBT device 10 can be annealed by placing the HBT device 10 on a hot plate and heating the HBT device 10 at about 200° C. to about 300° C. for about 15 minutes to about 60 minutes. In one aspect of the invention, the HBT device 10 is heated at about 260° C. for about 15 minutes. The platinum contact portion can have a thickness of about 30 Å to about 120 Å and diffuse within the emitter contact portion 24 to about 1.7 times its original thickness during the annealing process.

The emitter contact 34 also includes an adhesive contact portion 28 overlying the platinum/semiconductor alloyed diffusion contact barrier 26. The adhesive contact portion 28 could be formed of titanium and have a thickness of about 200 Å to about 500 Å. Alternatively, the adhesive contact portion 28 could be silicon, chromium or other elements or compounds that provide or promote layer adhesion. The emitter contact 34 also includes a barrier contact portion 30 overlying the adhesive contact portion 28. The barrier contact portion 30 can be formed of platinum and have a thickness of about 200 Å to about 1000 Å. Alternatively, the barrier contact portion 30 could be formed of other elements or compounds that provide or promote diffusion of a gold contact portion 32 overlying the barrier contact portion 30. The gold contact portion 32 has a thickness of about 1000 Å to about 5000 Å.

Turning now to FIGS. 2-7, process blocks in connection with fabrication of the HBT device 10 of FIG. 1 are described in accordance with an aspect of the present invention are described. Referring to FIG. 2, an HBT structure 11 is provided that includes the substrate 12 (e.g., InP substrate) or wafer with several stacked layers disposed above the substrate 12 to form the HBT structure 11. The collector portion 15 resides over the substrate 12, the base portion 17 overlays the collector portion 15 and the emitter portion 19 overlays the base portion 17. Each layer of the collector portion 15, the base portion 17 and the emitter portion 19 can be formed by epitaxial growth of each layer. It is to be appreciated that any suitable technique for forming the various layers can be employed such as Molecular Beam Epitaxy (MBE), Metal Organic Chemical Vapor Deposition (MOCVD) and Chemical Beam Epitaxy (CBE). It is to be appreciated that other layers can be added such as emitter caps, etch stops and grading layers without appreciably modifying the fabrication of the HBT structure 11. The collector contact 38 is coupled to the collector portion 15 and the base contact 36 is coupled to the base portion 17. The collector contact 38 and base contact 36 can be formed by conventional metal deposition and photolithography techniques.

As previously stated, the collector portion 15 includes a subcollector layer 14 overlying the InP substrate 12 and a collector layer 16 overlying the subcollector layer 14. The subcollector layer 14 is coupled to the collector contact 38 and can be heavily doped n+ Indium Gallium Arsenide (InGaAs). The collector layer 16 can be lightly doped n− InGaAs or InP. The base portion 17 includes the base layer 18 overlying the collector layer 16. The base layer 18 is coupled to the base contact 36 and can be heavily doped p+InGaAs or Gallium Arsenide Antimonide (GaAsSb). The emitter portion 19 includes the first emitter layer 20 overlying the base layer 18, the second emitter layer 22 overlying the first emitter layer 20 and the emitter contact layer 24 overlying the second emitter layer 22. The first emitter layer 20 can be formed of lightly doped n− Indium Aluminum Arsenide InAlAs or InP and the second emitter layer 22 can be formed of heavily doped n+ InAlAs or InP. The emitter contact layer 24 can be formed of heavily doped n+ InGaAs.

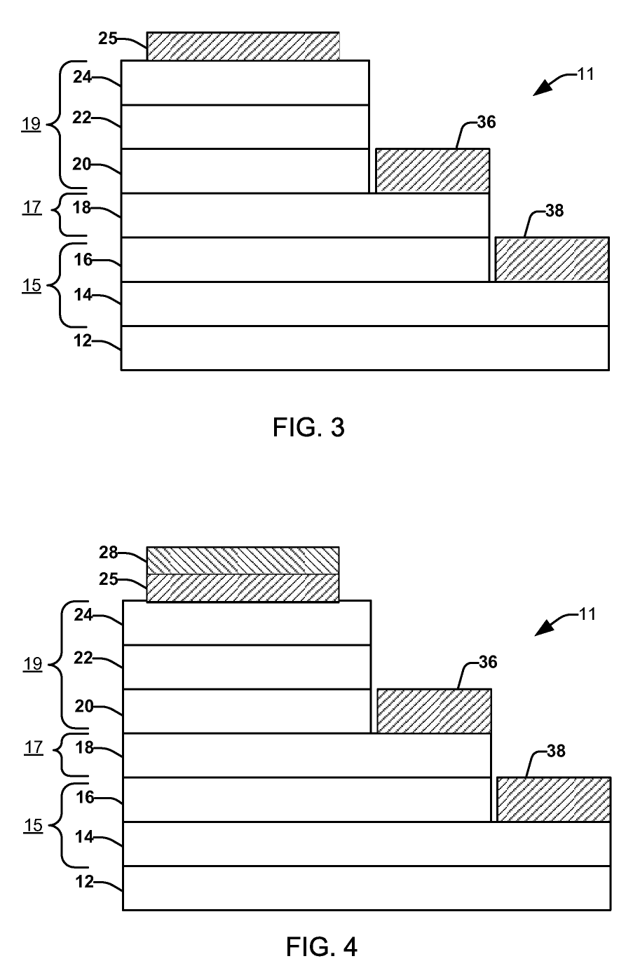

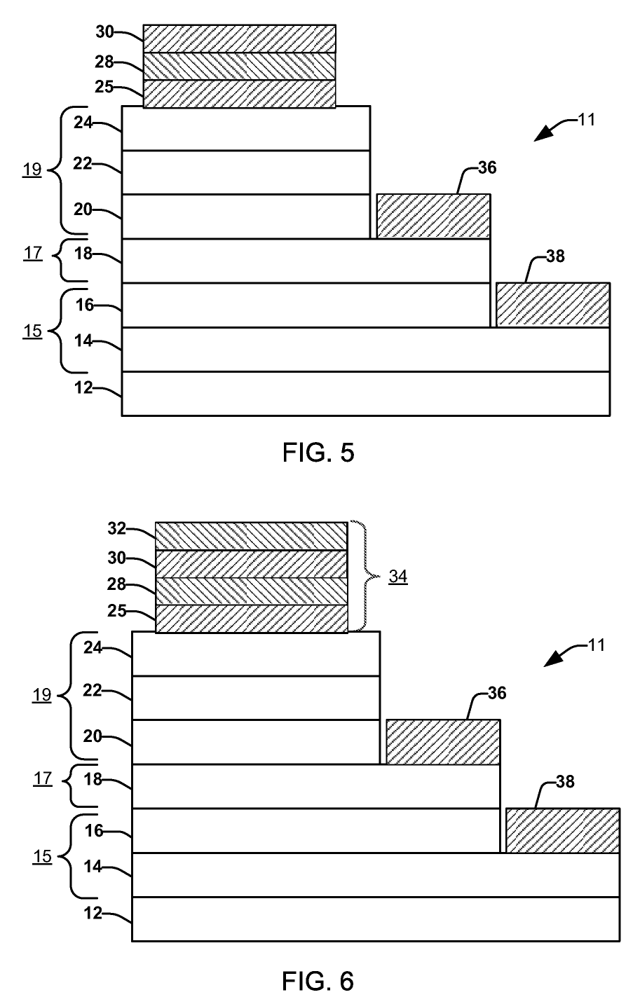

FIGS. 3-7 illustrated the formation of the emitter contact 34 of FIG. 1. A platinum layer is deposited over the emitter contact layer and the platinum layer is etched to provide a platinum contact portion 25, as illustrated in FIG. 3. The platinum contact portion 25 can have a thickness of about 30 Å to about 120 Å. An adhesive layer is deposited over the platinum contact portion 25 and the adhesive layer is etched to provide an adhesive contact portion 28, as illustrated in FIG. 4. The adhesive contact portion 28 could be formed of titanium and have a thickness of about 200 Å to about 500 Å. A barrier layer is deposited over the adhesive contact portion 28 and the barrier layer is etched to provide a barrier contact portion 30, as illustrated in FIG. 5. The barrier contact portion 30 mitigates the diffusion of the subsequent gold contact portion 32. The barrier contact portion 30 can be formed of platinum and have a thickness of about 200 Å to about 100 Å. A gold layer is deposited over the barrier contact portion 30 and the gold layer is etched to provide the gold contact portion 32, as illustrated in FIG. 6. The gold contact portion 32 can have a thickness of about 1000 Å to about 5000 Å.

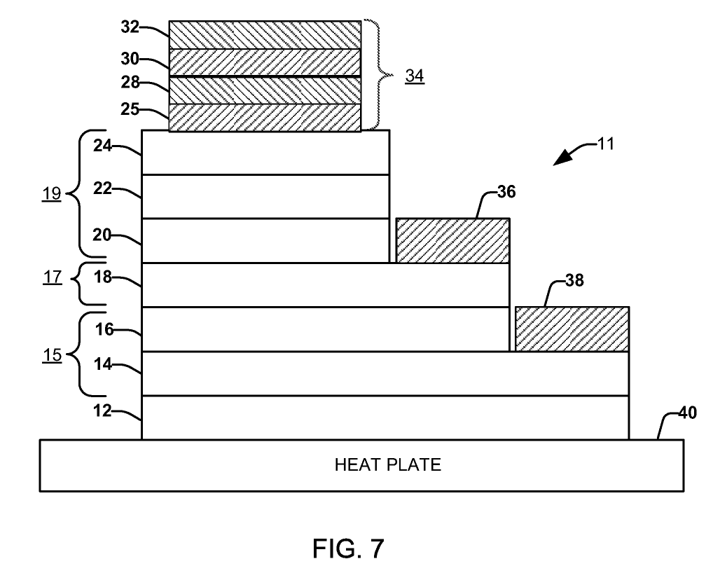

The HBT structure 11 of FIG. 6 is then disposed on a heat plate 40 during an annealing process, as illustrated in FIG. 7. The HBT structure 11 is heated at about 200° C. to about 300° C. for about 15 minutes to about 60 minutes. In one aspect of the invention, the HBT structure 11 is heated at about 260° C. for about 15 minutes. The platinum contact portion 25 diffuses into the semiconductor of the emitter contact portion 24 to about 1.7 times the original thickness of the platinum contact portion 25 to form the platinum/semiconductor alloyed diffusion contact barrier 26, as illustrated in FIG. 1.

What has been described above includes exemplary implementations of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations.

What is claimed is:

1. A method for fabricating a semiconductor device, the method comprising:
providing a semiconductor structure with a N-type doped semiconductor contact layer;
forming a platinum contact portion over the N-type doped semiconductor contact layer;
forming an adhesive contact portion over the platinum contact portion;
forming a barrier contact portion over the adhesive contact portion;
forming a gold contact portion over the barrier contact portion; and
annealing the semiconductor structure to alloy the platinum contact portion with the N-type doped semiconductor contact layer to form a platinum/semiconductor alloyed diffusion contact barrier substantially disposed within the N-type doped semiconductor contact layer.

2. The method of claim 1, wherein the semiconductor structure is an Indium Phosphide (In P) based heterojunction bipolar transistor (HBT).

3. The method of claim 1, wherein the semiconductor contact layer is Indium Gallium Arsenide (InGaAs).

4. The method of claim 1, wherein the forming a platinum contact portion over the N-type doped semiconductor contact layer comprises forming a platinum contact portion that has a thickness of about 30 Å to about 120 Å.

5. The method of claim 4, wherein the annealing the semiconductor structure comprises heating the semiconductor structure at about 200° C. to about 300° C. for about 15 minutes to about 60 minutes.

6. The method of claim 5, wherein the annealing the semiconductor structure comprises heating the semiconductor structure at about 260° C. for about 15 minutes.

7. The method of claim 1, wherein the forming an adhesive contact portion over the platinum contact portion comprises forming a titanium contact portion that has a thickness of about 200 Å to about 500 Å.

8. The method of claim 1, wherein the forming a barrier contact portion over the adhesive contact portion comprises forming a second platinum contact portion that has a thickness of about 200 Å to about 1000 Å.

9. The method of claim 1, wherein the forming a gold contact portion over the barrier contact portion comprises forming a gold contact portion that has a thickness of about 1000 Å to about 5000 Å.

10. The method of claim 1, wherein the N-type doped semiconductor contact layer is an emitter contact layer of an Indium Phosphide (InP) based heterojunction bipolar transistor (HBT), the emitter contact layer being formed from N-type doped Indium Gallium Arsenide (InGaAs) and overlies at least one layer of N-type doped Indium Aluminum Arsenide (InAlAs) or Indium Phosphide (InP).

11. A method for fabricating an Indium Phosphide (InP) based heterojunction bipolar transistor (HBT) device, the method comprising:
providing a HBT device with a N-type doped emitter contact layer;
forming a first platinum contact portion over the N-type doped emitter contact layer;
forming a titanium contact portion over the first platinum contact portion;
forming a second platinum contact portion over the titanium contact portion;
forming a gold contact portion over the barrier contact portion; and
annealing the HBT at a temperature of about 200° C. to about 300° C. for about 15 minutes to about 60 minutes to alloy the first platinum contact portion with the N-type doped emitter contact layer to form a platinum/semiconductor alloyed diffusion contact barrier substantially disposed within the emitter contact layer.

12. The method of claim 11, wherein the forming a first platinum contact portion over the N-type doped emitter contact layer comprises forming a first platinum contact portion that has a thickness of about 30 Å to about 120 Å.

13. The method of claim 12, wherein the titanium contact portion has a thickness of about 200 Å to about 500 Å, the second platinum contact portion has a thickness of about 200 Å to about 1000 Å and the gold contact portion has a thickness of about 1000 Å to about 5000 Å.

14. The method of claim 11, wherein the annealing the semiconductor structure comprises heating the semiconductor structure at about 260° C. for about 15 minutes.

15. The method of claim 11, wherein the N-type doped emitter contact layer is formed from N-type doped Indium Gallium Arsenide (InGaAs) and overlies at least one layer of N-type doped Indium Aluminum Arsenide (InAlAs) or Indium Phosphide (InP).

16. An Indium Phosphide (InP) based heterojunction bipolar transistor (HBT) device comprising:
a N-type doped emitter contact layer;
a platinum/semiconductor alloyed diffusion contact barrier substantially disposed within the N-type emitter contact layer;
an adhesive contact portion overlying the platinum/semiconductor alloyed diffusion contact barrier;
a barrier contact portion overlying the adhesive contact portion; and
a gold contact portion overlying the barrier contact portion.

17. The HBT device of claim 16, wherein the adhesive contact portion is a titanium contact portion and the barrier contact portion is a second platinum contact portion.

18. The HBT device of claim 17, wherein the titanium contact portion has a thickness of about 200 Å to about 500 Å, the second platinum contact portion has a thickness of about 200 Å to about 1000 Å and the gold contact portion has a thickness of about 1000 Å to about 5000 Å.

19. The HBT device of claim 16, wherein the N-type doped emitter contact layer is formed from N-type doped Indium Gallium Arsenide (InGaAs).

20. The HBT device of claim 16, wherein the platinum/semiconductor alloyed diffusion contact barrier has a thickness of about 50 Å to about 200 Å
